(19) United States
(12) Patent Application Publication
(10) Pub. No.: US 2024/0083807 A1
(43) Pub. Date: Mar. 14, 2024

(54) Reflective Coating

(71) Applicant: Vitro Flat Glass LLC, Cheswick, PA (US)

(72) Inventors: Zhixun Ma, Richmond, CA (US); Adam D. Polcyn, Pittsburgh, PA (US); Dennis J. O'Shaughnessy, Allison Park, PA (US)

(21) Appl. No.: 18/244,958

(22) Filed: Sep. 12, 2023

Related U.S. Application Data
(60) Provisional application No. 63/406,330, filed on Sep. 14, 2022.

(51) Int. Cl. C03C 17/36; C23C 14/02; C23C 14/06; C23C 14/08; C23C 14/10; C23C 14/18; C23C 14/35

(52) U.S. Cl. CPC C03C 17/3649; C03C 17/3626; C03C 17/3663; C23C 14/024; C23C 14/0652; C23C 14/081; C23C 14/10; C23C 14/185; C23C 14/352; G02B 27/144

(57) ABSTRACT

A coated article includes a substrate and a metal functional layer over at least a portion of the substrate. The metal functional layer includes a metal alloy selected from the group consisting of a silicon aluminum alloy and a silicon cobalt alloy. Another coated article includes a glass substrate and a coating over at least a portion of the substrate. The coating includes a dielectric layer, a metal functional layer, and a protective layer. The present invention also provides methods of making coated articles.

### CROSS REFERENCE TO RELATED APPLICATION

This application claims priority to U.S. Provisional Application No. 63/406,330, filed Sep. 14, 2022, the disclosure of which is incorporated herein by reference in its entirety.

### BACKGROUND OF THE INVENTION

### Field of the Invention

The invention relates generally to a coated article including a substrate and a metal functional layer comprising a metal alloy and methods of making coated articles thereof.

### Technical Considerations

High temperature fabrication processes such as pyrolytic spray process can allow for coatings to be mechanically and chemical durable, such that the coating may be used on the first surface of architectural glass windows. However, the coatings can be rough with poor film quality, and the materials quality and thickness cannot be precisely controlled by this spray technology. As an alternative, magnetron sputtering vapor deposition (MSVD) is an advanced technology for both materials quality and uniformity of thickness and composition. Typical MSVD coatings are soft due to the low temperature process, and do not have good endurance properties. Therefore, it would be desirable to provide a coating that can be deposited by MSVD that has enhanced chemical and mechanical durability.

A smart mirror (two-way mirror, also called a one-way mirror), is a reciprocal mirror that is reflective on one side and transparent on the other. The perception of one-way transmission is achieved when one side of the mirror is brightly lit and the other side is dark. This allows viewing from the darkened side but not vice versa. Light always passes equally in both directions; however, when one side is brightly lit and the other kept dark, the darker side becomes difficult to see from the brightly lit side because it is masked by the much brighter reflection of the lit side.

Smart mirrors have several useful applications. For example, when a smart mirror is placed in front of displays of electronic devices such as computers and TV, one can see the information behind when the display is on because of transparency of the smart mirror, but one cannot see the information on display because of high reflectivity of the front surface and the darkness of the display on the other side. Another application of smart mirrors is for police interrogation rooms. In this case, the smart mirror can allow police officers to see a suspect being interrogated in a room which is bright, and a number of other officers to carefully observe him from another room which is dark through a one-way mirror. Suspects are unable to see the police officers in the dark rooms, but the police officers are able to see the suspect through the smart mirror.

### SUMMARY OF THE INVENTION

A coated article of the invention comprises a substrate and a metal functional layer over at least a portion of the substrate. The metal functional layer comprises a metal alloy selected from the group consisting of a silicon aluminum alloy and a silicon cobalt alloy.

Another coated article of the invention comprises a glass substrate and a coating over at least a portion of the substrate. The coating comprises a dielectric layer over the substrate, a metal functional layer, and a protective layer over the metal functional layer. The metal functional layer comprises a metal alloy selected from the group consisting of a silicon aluminum alloy and a silicon cobalt alloy.

The invention also relates to a method of making a coated article, the method comprising providing a substrate and forming a metal functional layer over at least a portion of the substrate. The metal functional layer comprises a metal alloy selected from the group consisting of a silicon aluminum alloy and a silicon cobalt alloy. The metal functional layer is formed by a process comprising depositing, by a magnetron sputtering vapor deposition method, the metal alloy.

The invention also relates to a method of making a coated article, the method comprising providing a substrate and forming a coating over at least a portion of the substrate. The coating comprises a dielectric layer over the substrate, a metal functional layer, and a protective layer over the metal functional layer. The metal functional layer comprises a metal alloy selected from the group consisting of a silicon aluminum alloy and a silicon cobalt alloy. The metal functional layer is formed by a process comprising depositing, by a magnetron sputtering vapor deposition method, the metal alloy.

### BRIEF DESCRIPTION OF THE DRAWINGS

The invention will be described with reference to the following drawing figures wherein like reference numbers identify like parts throughout.

FIG. 1A is a side view (not to scale) of a substrate having a coating of the invention.

FIG. 1B is a side view (not to scale) of an insulating glass unit (IGU) having a coating of the invention.

FIG. 2 is a side view (not to scale) of a coating incorporating features of the invention.

FIG. 3 is a side view (not to scale) of another coating incorporating features of the invention.

FIG. 4 is a side view (not to scale) of another coating incorporating features of the invention.

FIG. 5 is a side view (not to scale) of another coating incorporating features of the invention.

FIG. 6 is a side view (not to scale) of another coating incorporating features of the invention.

FIG. 7 is a side view (not to scale) of another coating incorporating features of the invention.

FIG. 8 is a side view (not to scale) of another coating incorporating features of the invention.

### DESCRIPTION OF THE INVENTION

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. Further, as used herein, the terms “formed over”, “deposited over”, or “provided over” mean formed, deposited, or provided on but not necessarily in contact with the surface. For example, a coating layer “formed over” a substrate does not preclude the presence of one or more other coating layers or films of the same or different composition located between the formed coating layer and the substrate. As used herein, the terms “polymer” or “polymeric” include oligomers, homopolymers, copolymers, and terpolymers, e.g., polymers formed from two or more types of monomers or polymers. The terms “visible region” or “visible light” refer to electromagnetic radiation having a wavelength in the range of 380 nm to 800 nm. The terms “infrared region” or “infrared radiation” refer to electromagnetic radiation having a wavelength in the range of greater than 800 nm to 100,000 nm. The terms “ultraviolet region” or “ultraviolet radiation” mean electromagnetic energy having a wavelength in the range of 300 nm to less than 380 nm. Additionally, all documents, such as, but not limited to, issued patents and patent applications, referred to herein are to be considered to be “incorporated by reference” in their entirety. As used herein, the term “film” refers to a coating region of a desired or selected coating composition. A “layer” can comprise one or more “films”, and a “coating” or “coating stack” can comprise one or more “layers”. The terms “metal” and “metal oxide” include silicon and silica, respectively, as well as traditionally recognized metals and metal oxides, even though silicon conventionally may not be considered a metal. Thickness values, unless indicated to the contrary, are geometric thickness values.

The discussion of the invention may describe certain features as being “particularly” or “preferably” within certain limitations (e.g., “preferably”, “more preferably”, or “most preferably”, within certain limitations). It is to be understood that the invention is not limited to these particular or preferred limitations but encompasses the entire scope of the disclosure.

Weight percentages (wt. %) of the metal oxides, metal alloys, metal nitrides, or metal oxynitrides, as used herein, are based on the total weight of the metal components and exclude the weight of any oxide, nitride, or oxynitride components. It will be readily appreciated by one having ordinary skill in the art that the weight percentages of the metal functional layer, as used herein, refer to the weight percentages of the metal targets used to deposit the metal functional layer.

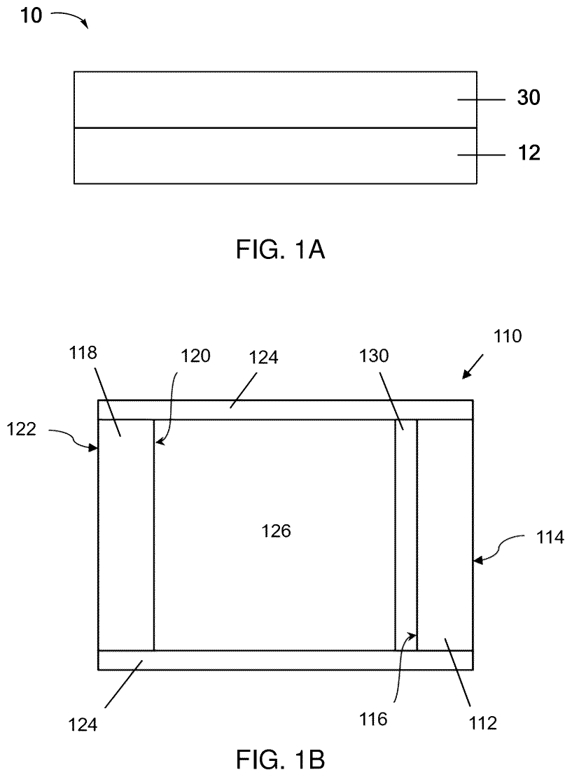

The invention is directed to a coated article. The coated article may be a smart mirror. A smart mirror (two-way mirror, also called a one-way mirror), is a reciprocal mirror that is reflective on one side and transparent on the other. The coated article comprises a substrate. A metal functional layer is over at least a portion of the substrate. The metal functional layer comprises a metal alloy selected from the group consisting of a silicon aluminum alloy and a silicon cobalt alloy. Optionally, the coated article may also have a protective layer, a base layer, or a dielectric layer. For example, the coated article comprises a substrate that is coated with a coating (FIG. 1A). The coating comprises a dielectric layer, a metal functional layer, a protective layer and optionally a second dielectric layer and/or a base layer.

The coated article 10 comprises a substrate 12. The substrate 12 can be of any desired material having any desired characteristics, such as opaque, translucent, or transparent to visible light. For example, the substrate 12 can be transparent or translucent to visible light. By “transparent” is meant having visible light transmission of greater than 0% up to 100%. Alternatively, the substrate 12 can be translucent. By “translucent” is meant allowing electromagnetic energy (e.g., visible light) to pass through but diffusing this energy such that objects on the side opposite the viewer are not clearly visible. Examples of suitable materials include, but are not limited to, plastic substrates (such as acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); ceramic substrates; glass substrates; or mixtures or combinations of any of the above. For example, the substrate 12 can be conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as conventional float glass, and can be of any composition having any optical properties, e.g., any value of visible transmission, ultraviolet transmission, infrared transmission, and/or total solar energy transmission. By “float glass” is meant glass formed by a conventional float process in which molten glass is deposited onto a molten metal bath and controllably cooled to form a float glass ribbon. Examples of float glass processes are disclosed in U.S. Pat. Nos. 4,466,562 and 4,671,155.

The substrate 12 may comprise, for example, clear float glass or can be tinted or colored glass. The substrate 12 can be of any desired dimensions, e.g., length, width, shape, or thickness. In one non-limiting embodiment, the substrate 12 may be 1 mm to 30 mm thick, such as 2.5 mm to 25 mm thick, such as 2.5 mm to 10 mm.

In some embodiments, the substrate 12 can be a monolithic glazing. By “monolithic” is meant having a single structural support or structural member, e.g. having a single substrate.

The coated article has a metal functional layer 60 deposited over at least a portion of a major surface of a substrate 12. The metal functional layer 60 provides (a) reflectance of electromagnetic radiation in at least a portion of the infrared radiation region of the electromagnetic spectrum, for example, in the solar infrared radiation region and/or the thermal infrared radiation region of the electromagnetic spectrum, and/or (b) absorptivity of electromagnetic radiation in at least a portion of one or more regions of the electromagnetic spectrum, for example, the visible radiation region and/or the infrared radiation region and/or the ultraviolet radiation region of the electromagnetic spectrum. The metal functional layer 60 can comprise a metal alloy, such as but not limited to a metal alloy comprising silicon and/or cobalt. Non-limiting examples of suitable metal alloys include a silicon aluminum alloy and a silicon cobalt alloy.

In some embodiments, the metal functional layer 60 may be substantially free, may be essentially free, or may be completely free of iron. The term “substantially free” as used in this context means the metal functional layer contains less than 1 wt. % iron, “essentially free” means the metal functional layer contains less than 0.1 wt. % iron, and “completely free” means less than 0.01 wt. % iron.

In another exemplary embodiment, the metal functional layer 60 comprises silicon. For example, the metal functional layer 60 may comprise a metal alloy comprising silicon in the range of 50 wt. % to 99 wt. %, from 60 wt. % to 99 wt. %, from 75 wt. % to 99 wt. %, from 80 wt. % to 99 wt. %, from 85 wt. % to 99 wt. %, or from 90 wt. % to 99 wt. %. In one non-limiting embodiment, the metal functional layer 60 comprises a silicon aluminum alloy comprising from 70 wt. % to 100 wt. % silicon and from 0 wt. % to 30 wt. % aluminum, such as from 80 wt. % to 95 wt. % silicon and from 5 wt. % to 20 wt. % aluminum; such as from 85 wt. % to 99 wt. % silicon and from 1 wt. % to 15 wt. % aluminum, such as from 85 wt. % to 95 wt. % silicon and from 5 wt. % to 15 wt. % aluminum, or from 90 wt. % to 95 wt. % silicon and from 5 wt. % to 10 wt. % aluminum.

In another exemplary embodiment, the metal functional layer comprises silicon and cobalt. For example, the metal functional layer 60 may comprise a metal alloy comprising silicon in the range of 30 wt. % to 85 wt. % and cobalt in the range of 15 wt. % to 70 wt. %, such as from 50 wt. % to 90 wt. % silicon and from 10 wt. % to 50 wt. % cobalt, such as from 50 wt. % to 70 wt. % silicon and from 30 wt. % to 50 wt. % cobalt, such as from 65 wt. % to 75 wt. % silicon and from 25 wt. % to 35 wt. % cobalt.

The metal functional layer 60 can have any desired thickness, such as in the range of from 1 nanometer (nm) to 100 nm, from 5 nm to 50 nm, from 10 nm to 50 nm, from 10 nm to 45 nm, from 20 nm to 40 nm, from 20 nm to 50 nm, from 20 nm to 60 nm, from 30 nm to 45 nm, from 10 nm to 35 nm, or from 20 nm to 30 nm.

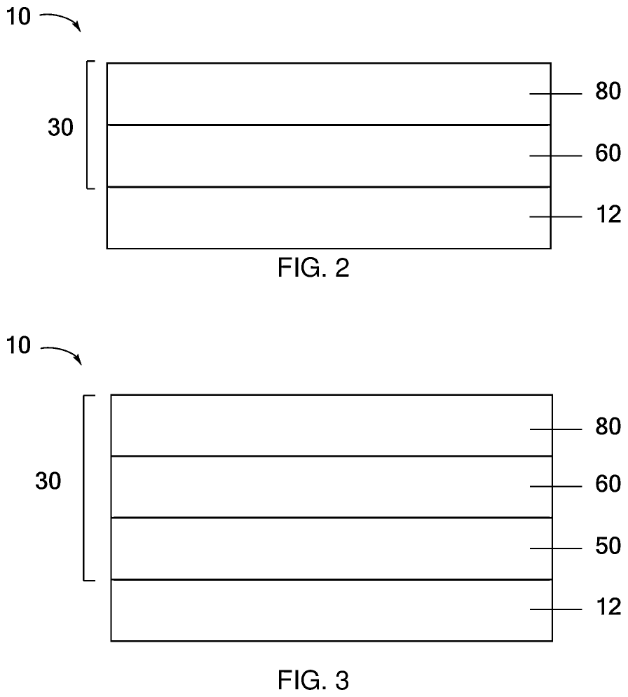

The coated article 10 can include a protective layer 80, which, for example in the non-limiting embodiment shown in FIG. 2, is deposited over the metal functional layer 60, to assist in protecting the underlying layers, such as the metal functional layer, from mechanical and chemical attack during processing. The protective layer 80 can be the outermost layer of the coating 30. The protective layer 80 can be an oxygen barrier coating layer to prevent or reduce the passage of ambient oxygen into the underlying layers of the coating 30, such as during heating or bending. The protective layer 80 can be of any desired material or mixture of materials. For example, the protective layer can comprise a metal oxide layer, a metal nitride layer, or mixtures thereof. In one exemplary embodiment, the protective layer 80 can include a layer having one or more metal oxide materials, such as but not limited to oxides of aluminum, silicon, or mixtures thereof. For example, the protective coating 80 can be a single coating layer comprising in the range of 0 wt. % to 100 wt. % alumina and/or 100 wt. % to 0 wt. % silica, such as 5 wt. % to 95 wt. % alumina 45 and 95 wt. % to 5 wt. % silica, such as 10 wt. % to 90 wt. % alumina and 90 wt. % to 10 wt. % silica, such as 15 wt. % to 90 wt. % alumina and 85 wt. % to 10 wt. % silica, such as 50 wt. % to 75 wt. % alumina and 50 wt. % to 25 wt. % silica, such as 50 wt. % to 70 wt. % alumina and 50 wt. % to 30 wt. % silica, such as 35 wt. % to 100 wt. % alumina and 65 wt. % to 0 wt. % silica, e.g., 70 wt. % to 90 wt. % alumina and 30 wt. % to 10 wt. % silica, e.g., 75 wt. % to 85 wt. % alumina and 25 wt. % to 15 wt. % of silica, e.g., 88 wt. % alumina and 12 wt. % silica, e.g., 65 wt. % to 75 wt. % alumina and 35 wt. % to 25 wt. % silica, e.g., 70 wt. % alumina and 30 wt. % silica, e.g., 60 wt. % to less than 75 wt. % alumina and greater than 25 wt. % to 40 wt. % silica. Other materials, such as aluminum, chromium, hafnium, yttrium, nickel, boron, phosphorous, titanium, zirconium, and/or oxides thereof, can also be present, such as to adjust the refractive index of the protective layer 80. In one non-limiting embodiment, the refractive index of the protective layer 80 can be in the range of 1 to 3, such as 1 to 2, such as 1.4 to 2, such as 1.4 to 1.8.

In one non-limiting embodiment, the protective layer 80 is a combination silica and alumina coating. The protective coating 80 can be sputtered from two cathodes (e.g., one silicon and one aluminum) or from a single cathode containing both silicon and aluminum. This silicon/aluminum oxide protective layer 80 can be written as SiₓAl₁₋ₓO_{(1.5+x)/2}, where x can vary from greater than 0 to less than 1.

In another non-limiting embodiment, the protective layer 80 comprises a combination of titania and alumina.

In one non-limiting embodiment, the protective layer 80 may be comprised of silicon oxide (SiOₓ), silicon nitride (Si₃N₄ or SiNₓ), silicon oxynitride (SiOₓN_{y}), silicon aluminum oxide (SiAlOₓ) silicon aluminum nitride (SiAlNₓ), silicon aluminum oxynitride (SiAlOₓN_{y}), a mixture thereof, and/or an alloy thereof, and which may provide increased durability to the metal functional layer 60. The protective layer 80 may be formed of silicon nitride deposited with other materials having superior electrical conductivity to improve sputtering of the silicon. For example, during deposition, the silicon cathode can include a small amount (e.g., up to 20 wt. %, up to 15 wt. %, up to 10 wt. %, or up to 5 wt. %) of aluminum to improve sputtering. In which case, the resultant silicon nitride protective layer would include a small percentage of aluminum, e.g., up to 15 wt. % aluminum, e.g., up to 10 wt. % aluminum, e.g., up to 5 wt. % aluminum. A coating layer deposited from a silicon cathode having up to 10 wt. % aluminum (added to enhance the conductivity of the cathode) is referred to herein as “a silicon nitride” layer, even though a small amount of aluminum may be present. The small amount of aluminum in the cathode (e.g., less than or equal to 15 wt. %, such as less than or equal to 10 wt. %, such as less than or equal to 5 wt. %) is believed to form aluminum nitride in the predominantly silicon nitride protective layer 80. The protective layer 80 may be formed in a nitrogen atmosphere; however, it is to be understood that other gases, such as oxygen, may be present in the atmosphere during the deposition of the protective layer 80.

The protective layer can be of any desired thickness. The protective layer 80 can have a thickness in the range of from 1 nm to 250 nm, from 1 nm to 150 nm, from 5 nm to 150 nm, from 10 nm to 120 nm, from 100 nm to 140 nm, from 5 nm to 70 nm, from 30 nm to 70 nm, from 5 nm to 30 nm, or from 10 nm to 30 nm. The protective layer 80 is the outermost layer of the coated article. Further, the protective layer 80 can be of non-uniform thickness. By “non-uniform thickness” is meant that the thickness of the protective layer 80 can vary over a given unit area, e.g., the protective layer 80 can have high and low spots or areas.

In another non-limiting embodiment, the protective layer 80 can be a multilayer coating comprising a first film and a second film formed over the first film. The first film can comprise alumina, silica, titania, zirconia, tin oxide, or mixtures thereof. In one specific non-limiting embodiment, the first film can comprise alumina or a mixture or alloy comprising alumina and silica. For example, the first film can comprise a silica/alumina mixture having greater than 5 wt. % alumina, such as greater than 10 wt. % alumina, such 30 as greater than 15 wt. % alumina, such as greater than 30 wt. % alumina, such as greater than 40 wt. % alumina, such as 50 wt. % to 70 wt. % alumina, such as in the range of 60 wt. % to 100 wt. % alumina and 0 wt. % to 40 wt. % silica, e.g. 60 wt. % alumina and 40 wt. % silica. In another example, the first layer can comprise zinc stannate. In another example, the first film can comprise zirconia. In one non-limiting embodiment, the first film can have a thickness in the range of greater than 0 nm to 1000 nm, such as 10 nm to 25 nm, such as 10.1 nm to 25 nm, such as 15 nm to 20 nm, such as 16 nm.

The second film of the protective layer 80 may comprise, for example, a metal oxide or metal nitride. The second film can be titania, alumina, silica, zirconia, tin oxide, a mixture thereof, or an alloy thereof. For example, the second film may include a mixture of titania and alumina; a mixture of titania and silica; or zirconia. An example of the second film can comprise a titania/alumina mixture having 40 wt. % to 60 wt. % alumina, and 40 wt. % to 60 wt. % titania; 45 wt. % to 55 wt. % alumina, and 45 wt. % to 55 wt. % titania; 48 wt. % to 52 wt. % alumina, and 48 wt. % to 52 wt. % titania; 49 wt. % to 51 wt. % alumina, and 49 wt. % to 51 wt. % titania; or 50 wt. % alumina, and 50 wt. % titania. An example of the second film may include titanium aluminum oxide (TiAlO). Another example of the second film is a silica/alumina mixture having greater than 40 wt. % silica, such as greater than 50 wt. % silica, such as greater than 60 wt. % silica, such as greater than 70 wt. % silica, such as greater than 80 wt. % silica, such as in the range of 80 wt. % to 90 wt. % 45 silica and 10 wt. % to 20 wt. % alumina, e.g., 85 wt. % silica and 15 wt. % alumina. In one non-limiting embodiment, the second film can have a thickness in the range of greater than 0 nm to 2,000 nm, such as 5 nm to 500 nm, such as 5 nm to 200 nm, such as 10 nm to 100 nm, such as 20 nm to 50 nm, such as 22 nm to 35 nm, such as 22 nm. Non-limiting examples of suitable protective layers are described, for example, in U.S. Patent Application Publication Nos. 2004/0106017 A1; 2002/0172775 A1; 2003/0228484 A1; 2004/0023080 A1; 2004/0023038 A1; and 2003/0228476 A1.

In non-limiting examples, the protective layer 80 may include an additional third film formed over the second film. This third film can be any of the materials used to form the first film or the second film. The third film, for example, can comprise alumina, silica, titania, zirconia, tin oxide, or mixtures thereof. For example, the third film can comprise a mixture of silica and alumina. In another example, the third film comprises zirconia.

In one non-limiting embodiment, the coated article can include a base layer 50, which, for example as shown in FIG. 3, is deposited over the substrate 12 and under the metal functional layer 60. The base layer 50 may provide the coated article with various performance advantages, such as acting as a sodium ion barrier between the substrate 12 and the overlying coating layers. The base layer 50 can comprise any of the materials described above with respect to the outermost protective layer 80. For example the base layer may be comprised of tin oxide (SnOₓ), silicon oxide (SiOₓ), silicon nitride (Si₃N₄ or SiNₓ), silicon oxynitride (SiOₓNₓ), silicon aluminum oxide (SiAlOₓ), silicon aluminum nitride (SiAlNₓ), silicon aluminum oxynitride (SiAlOₓNₓ), a mixture thereof, and/or an alloy thereof. The base layer 50 can be a multilayer coating comprising a first film and a second film formed over the first film. In one non-limiting embodiment, the base layer comprises one or more films, wherein each film comprises SnOₓ, SiOₓ, Si₃N₄, SiOₓNₓ, SiAlOₓ, SiAlNₓ, or SiAlOₓNₓ. For example, the base layer may comprise two films, wherein each film comprises SiAlOₓ or SiAlNₓ.

In one non-limiting embodiment, the base layer 50 may be comprised of a film of a metal nitride, such as Si₃N₄ and/or SiAlN, disposed over and in contact with a film of metal oxynitride, such as SiAlON. Examples of metal oxynitride films also, or alternatively, may include alloys and/or mixtures of a metal nitride.

The base layer 50 can be of any desired thickness. The base layer 50 can have a thickness in the range of from 1 nm to 250 nm, from 1 nm to 150 nm, from 5 nm to 150 nm, from 10 nm to 120 nm, from 15 nm to 100 nm, from 30 nm to 110 nm, from 100 nm to 140 nm, from 70 nm to 110 nm, or from 30 nm to 80 nm.

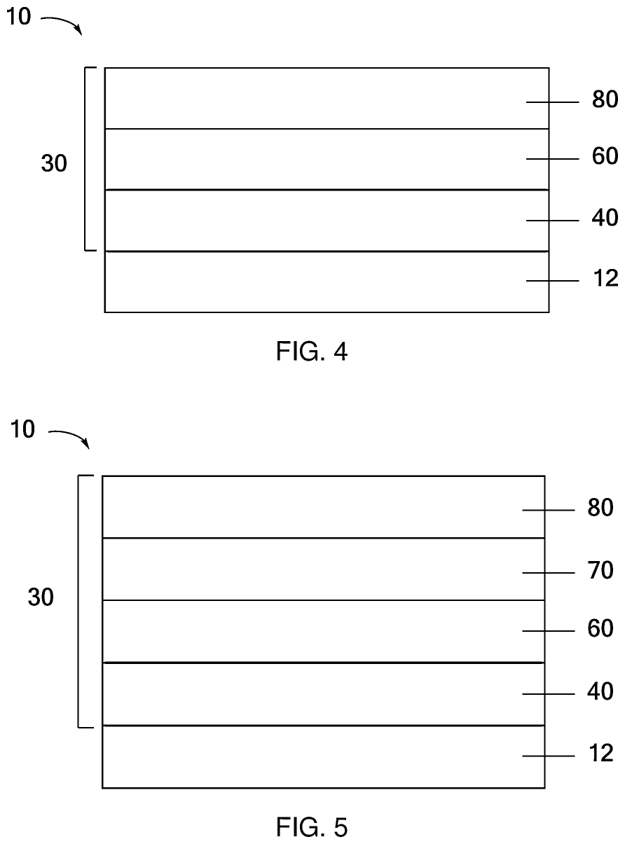

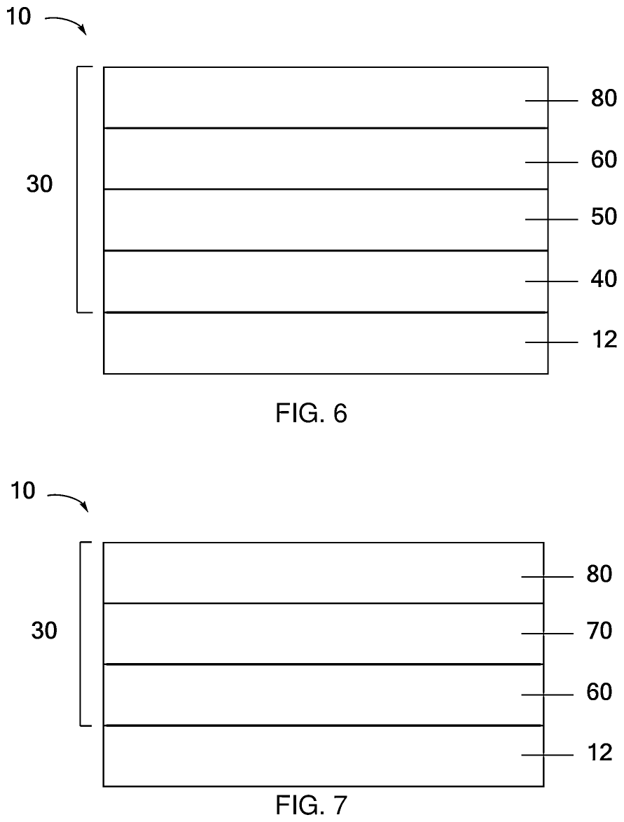

In one non-limiting embodiment, the coated article can include at least one dielectric layer. For example, a dielectric layer 40, which for example as shown in FIGS. 4, 5, and 6, is deposited over the substrate 12 and is under the metal functional layer 60. As shown in FIGS. 4 and 5, the dielectric layer 40 is deposited directly over the substrate 12 and is under the metal functional layer 60. In another embodiment, the coated article 10 includes a dielectric layer 40 that is deposited directly over the substrate 12 and is under the base layer 50 (FIG. 6).

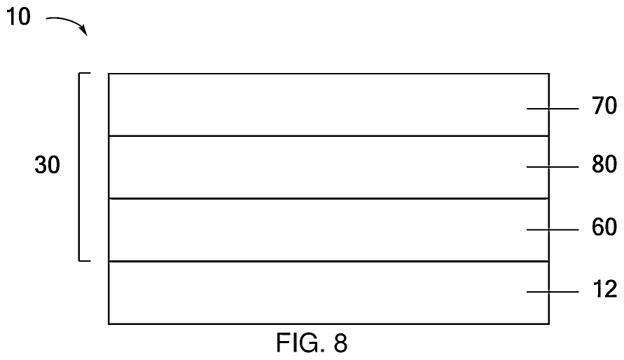

Alternatively, the coated article 10 can include a dielectric layer 70, which is deposited directly over the metal functional layer 60 and under the protective layer 80 (FIG. 7). In another non-limiting embodiment, the dielectric layer 70 is directly over the protective layer 80 and is the outermost layer (FIG. 8).

The dielectric layer(s) 40, 70 can be a single layer or can comprise more than one film of antireflective materials and/or dielectric materials, such as, but not limited to, metal oxides, oxides of metal alloys, metal nitrides, metal oxynitrides, or mixtures thereof. The dielectric layer(s) 40, 70 can be transparent to visible light. Examples of suitable metal oxides for the dielectric layer(s) 40, 70 include oxides of titanium, hafnium, zirconium, niobium, zinc, bismuth, lead, indium, tin, and mixtures thereof. These metal oxides can have small amounts of other materials, such as manganese in bismuth oxide, tin in indium oxide, etc. Additionally, oxides of metal alloys or metal mixtures can be used, such as oxides containing zinc and tin (e.g., zinc stannate, defined below), oxides of indium-tin alloys, silicon nitrides, silicon aluminum nitrides, or aluminum nitrides. Further, doped metal oxides, such as antimony or indium doped tin oxides or nickel or boron doped silicon oxides, can be used. The dielectric layer(s) 40, 70 can be a substantially single phase film, such as a metal oxide film, e.g., zinc stannate, or can be a mixture of phases composed of zinc and tin oxides or can be composed of a plurality of films. For example, the dielectric layer(s) may comprise one or more films selected from zinc tin oxides, zinc oxide, silica, silicon aluminum oxides, silicon nitride, aluminum nitride, silicon aluminum nitrides, titanium oxides, and titanium nitrides.

The dielectric layer(s) 40, 70 (whether a single film or multiple film layer) can have any thickness, such as in the range of from 1 nm to 200 nm, from 1 nm to 150 nm, from 1 nm to 100 nm, from 5 nm to 140 nm, from 5 nm to 100 nm, from 10 nm to 50 nm, from 30 nm to 70 nm, from 80 nm to 120 nm, from 100 nm to 140 nm, or from 1 nm to 10 nm.

The reflectivity of the coated article 10 may be increased when dielectric layer(s) 40, 70 having a high refractive index is utilized. In one non-limiting embodiment, the dielectric layer(s) 40, 70 may have a refractive index of at least 1.4, at least 1.5, at least 1.8, or at least 2.0. In one non-limiting embodiment, the dielectric layer(s) 40, 70 may have a refractive index in the range of 1.4 to 2.5, from 1.4 to 2.0, or from 1.5 to 2.0.

The coated article 10 may comprise more than one dielectric layer. Each dielectric layer may comprise the same or different materials and have the same or different thickness as the other dielectric layers. For example, the coated article 10 may comprise at least two dielectric layers. In one non-limiting embodiment, the coated article may have a dielectric layer 40 that is over the substrate 12 and under the metal functional layer 60 and a dielectric layer 70 that is over the metal functional layer 60 and under the protective layer 80, as shown in FIG. 5.

In one non-limiting embodiment, the coated article 10 can optionally include a primer layer over the metal functional layer 60. The primer layer can be a single film or a multiple film layer. The primer layer can include an oxygen-capturing material that can be sacrificial during the deposition process to prevent degradation or oxidation of the metal functional layer 60 during the sputtering process or subsequent heating processes. The primer layer can also absorb at least a portion of electromagnetic radiation, such as, visible light, passing through the coating 30. Examples of materials useful for the primer layer include titanium, silicon, silicon dioxide, silicon nitride, silicon oxynitride, nickel, zirconium, aluminum, cobalt, chromium, titanium, aluminum, an alloy thereof, or a mixture thereof. In one non-limiting embodiment, the primer layer comprises titanium, titanium and aluminum, or zinc and aluminum, which are deposited as a metal and at least a portion of the titanium, or titanium and aluminum, or zinc and aluminum are subsequently oxidized. In another embodiment, the primer layer comprises a nickel chromium alloy, such as, Inconel. In another embodiment, the primer layer comprises a cobalt-chromium alloy, such as, Stellite®.

The primer layer can have a thickness in the range of from 0.5 nm to 5 nm, such as, from 1 nm to 4 nm, such as, from 1 nm to 2.5 nm.

The invention is also related to a coated article comprising a glass substrate and a coating over at least a portion of the substrate. The coating comprises a dielectric layer over the substrate, a metal functional layer, and a protective layer over the metal functional layer, wherein the metal functional layer comprises a metal alloy selected from the group consisting of a silicon aluminum alloy and a silicon cobalt alloy. The dielectric layer, the metal functional layer, and the protective layer of the coating can be any of the layers previously described herein. Optionally, the coating further comprises a second dielectric layer and/or a base layer. The optional second dielectric layer and optional base layer of the coating are any of the layers previously described herein.

An exemplary non-limiting coated article 10 of the invention is shown in FIG. 2. The coated article 10 includes a metal functional layer 60 that is deposited over and optionally in direct contact with the substrate 12. The coated article 10 further includes a protective layer 80 that is deposited over and optionally in direct contact with the metal functional layer 60. The metal functional layer 60 and the protective layer 80 form the coating 30 that is over and optionally in direct contact with at least a portion of substrate 12. The substrate 12 may be glass.

Another exemplary non-limiting coated article 10 of the invention is shown in FIG. 3. The coated article 10 includes a base layer 50 that is deposited over and optionally in direct contact with the substrate 12. The coated article 10 further includes a metal functional layer 60 that is deposited over and optionally in direct contact with the base layer 50. The coated article 10 further includes an outermost protective layer 80 that is deposited over and optionally in direct contact with the metal functional layer 60. The base layer 50, the metal functional layer 60, and the protective layer 80 form the coating 30 that is over and optionally in direct contact with at least a portion of substrate 12. The substrate 12 may be glass.

Another exemplary non-limiting coated article 10 of the invention is shown in FIG. 4. The coated article 10 includes a dielectric layer 40 that is deposited over and optionally in direct contact with at least a portion of the substrate 12. The coated article 10 further includes a metal functional layer 60 that is deposited over and optionally in direct contact with the dielectric layer 40. The coated article 10 further includes a protective layer 80 that is deposited over and optionally in direct contact with the metal functional layer 60. The dielectric layer 40, the metal functional layer 60, and the protective layer 80 form the coating 30 that is over and optionally in direct contact with at least a portion of substrate 12. The substrate 12 may be glass.

Another exemplary non-limiting coated article 10 of the invention is shown in FIG. 5. The coated article 10 includes a first dielectric layer 40 deposited over and optionally in direct contact with at least a portion of the substrate 12. The coated article 10 further includes a metal functional layer 60 that is deposited over and optionally in direct contact with the first dielectric layer 40. The coated article 10 further includes a second dielectric layer 70 that is deposited over and optionally in direct contact with the metal functional layer 60. The coated article 10 further includes a protective layer 80 that is deposited over and optionally in direct contact with the second dielectric layer 70. The first dielectric layer 40, the metal functional layer 60, the second dielectric layer 70, and the protective layer 80 form the coating 30 that is over and optionally in direct contact with at least a portion of substrate 12. The substrate 12 may be glass.

Another exemplary non-limiting coated article 10 of the invention is shown in FIG. 6. The coated article 10 includes a dielectric layer 40 that is deposited over and optionally in direct contact with at least a portion of the substrate 12. The coated article 10 further includes a base layer 50 that is deposited over and optionally in direct contact with the dielectric layer 40. The coated article 10 further includes a metal functional layer 60 that is deposited over and optionally in direct contact with the base layer 50. The coated article 10 further includes a protective layer 80 that is deposited over and optionally in direct contact with the metal functional layer 60. The dielectric layer 40, the base layer 50, the metal functional layer 60, and the protective layer 80 form the coating 30 that is deposited over and optionally in direct contact with at least a portion of substrate 12. The substrate 12 may be glass.

Another exemplary non-limiting coated article 10 of the invention is shown in FIG. 7. The coated article 10 includes a metal functional layer 60 that is deposited over and optionally in direct contact with the substrate 12. The coated article 10 further includes a dielectric layer 70 that is deposited over and optionally in direct contact with the metal functional layer 60. The coated article 10 further includes a protective layer 80 that is deposited over and optionally in direct contact with the dielectric layer 70. The metal functional layer, the dielectric layer, and the protective layer form the coating 30 that is deposited over and optionally in direct contact with at least a portion of substrate 12. The substrate 12 may be glass.

Another exemplary non-limiting coated article 10 of the invention is shown in FIG. 8. The coated article 10 includes a metal functional layer 60 that is deposited over and optionally in direct contact with the substrate 12. The coated article 10 further includes a protective layer 80 that is deposited over and optionally in direct contact with the metal functional layer 60. The coated article 10 further includes a dielectric layer 70 that is deposited over and optionally in direct contact with protective layer 80. The metal functional layer 60, the protective layer 80, and the dielectric layer 70 form the coating 30 that is deposited over and optionally in direct contact with at least a portion of substrate 12. The substrate 12 may be glass.

The dielectric layer(s) 40, 70, the base layer 50, the metal functional layer 60, the protective layer 80, and the optional primer layer can be deposited by any conventional method, such as but not limited to conventional chemical vapor deposition (CVD) and/or physical vapor deposition (PVD) methods. Examples of CVD processes include spray pyrolysis. Examples of PVD processes include electron beam evaporation and vacuum sputtering (such as magnetron sputter vapor deposition (MSVD)). Other coating methods could also be used, such as but not limited to sol-gel deposition. In one non-limiting embodiment, the layers of the coating 30 can be deposited by MSVD. Examples of MSVD coating devices and methods will be well understood by one of ordinary skill in the art and are described, for example, in U.S. Pat. Nos. 4,379,040; 4,861,669; 4,898,789; 4,898,790; 4,900,633; 4,920,006; 4,938,857; 5,328,768; and 5,492,750. In one non-limiting embodiment, a cobalt chromium alloy is used as a magnetron sputtering target to deposit metal functional layer 60.

The coating 30 of the present invention can provide desirable physical properties including, but not limited to durability properties, such as humidity resistance and chemical resistance. With some non-limiting embodiments, the presence of the dielectric layer(s) 40, 70 and/or the protective layer 80 were found to enhance the durability of the coating.

The materials used for the coating layers, such as the metal functional layer 60, may be selected to achieve desired color properties of the coating 30. The coating 30 may consist essentially of the materials as described herein such that the desired color properties of the coating are achieved. For example, a coating 30 consisting essentially of the materials as described herein may include additional materials provided that the color properties of the coating are not affected. The color coordinates a*, b*, and L* are those of the conventional CIE (1931) and CIELAB systems that will be understood by one of ordinary skill in the art.

In one non-limiting practice of the invention, the coated article 10 has a transmittance L* in the range of 45 to 60. For example, in the range of 45 to 58, or 45 to 56.

In one non-limiting practice of the invention, the coated article 10 has a transmittance (T) a* in the range of −1.0 to 13.0. For example, in the range of −1.0 to −11.5, −0.5 to 13.0, −0.5 to −11.5, −0.5 to 1.0, 9.0 to 11.5, or 3.5 to 11.5.

In one non-limiting practice of the invention, the coated article 10 has a transmittance (T) b* in the range of −1.0 to 13.0. For example, in the range of −0.5 to 13.0, −0.5 to 7.5, 8.5 to 13.0, or 2.5 to 13.0.

In one non-limiting practice of the invention, the coated article 10 has a visible light transmittance (LTA) in the range of 15 to 35. For example, in the range of 15 to 30, 15 to 28, or 17 to 27.

In one non-limiting practice of the invention, the coated article 10 has a film side reflection (Rf) L* in the range of 70 to 90. For example, in the range of 75 to 90, 80 to 90, or 85 to 90. In one non-limiting practice of the invention, the coated article 10 has an Rf L* of at least 75, such as at least 80, or at least 85.

In one non-limiting practice of the invention, the coated article 10 has an Rf a* in the range of −10.0 to 0.0. For example, in the range of −9.0 to 0.0, −9.0 to −0.3, −8.5 to 0.0, −4.5 to 0.0, or −8.5 to −3.0.

In one non-limiting practice of the invention, the coated article 10 has an Rf b* in the range of −4.0 to 13.0. For example, in the range of −4.0 to 12.0, −3.0 to 12.0, or −2.0 to 0.0.

In one non-limiting practice of the invention, the coated article 10 has a glass side reflection (Rg) L* in the range of 70 to 85. For example, in the range of 72 to 85, 75 to 85, 72 to 82, or 75 to 82. In one non-limiting practice of the invention, the coated article 10 has an Rg L* of at least at least 70, such as at least 75, such as at least 80.

In one non-limiting practice of the invention, the coated article 10 has an Rg a* in the range of −10.0 to 0.0. For example, in the range of −9.0 to 0.0, −9.0 to −1.0, −9.0 to −2.0, or −8.0 to −2.0.

In one non-limiting practice of the invention, the coated article 10 has an Rg b* in the range of −6.0 to 15.0. For example, in the range of −5.5 to 15.0, −5.0 to 15.0, −5.0 to 4.5.

Certain embodiments of the present invention are particularly useful for coatings for smart mirrors or displays. For example, the coatings of the present invention can be applied to smart mirrors used for interrogation rooms or electronic display applications.

The present invention is also related to a method of making a coated article. A substrate is provided. A metal functional layer is formed over at least a portion of the substrate, wherein the metal functional layer comprises a metal alloy selected from the group consisting of a silicon aluminum alloy and a silicon cobalt alloy. The metal functional layer is formed by a process comprising depositing, by a magnetron sputtering vapor deposition method, the metal alloy. The method may also optionally further comprise forming a protective layer. The protective layer can be any of the protective layers described herein. The method may also optionally further comprises forming at least one dielectric layer. The at least one dielectric layer can be any one of the dielectric layers described herein. The method may also optionally further comprise forming a base layer. The base layer may be any of the base layers described herein.

The present invention is also related to a method of making a coated article, wherein a substrate is provided and a coating is formed over at least a portion of the substrate. The coating comprises a dielectric layer over the substrate. The coating comprises a metal functional layer. The coating comprises a protective layer over the metal functional layer. The metal functional layer comprises a metal alloy selected from the group consisting of a silicon aluminum alloy and a silicon cobalt alloy. The metal functional layer is formed by a process comprising depositing, by a magnetron sputtering vapor deposition method, the metal alloy. The dielectric layer and the protective layer can be any of the dielectric layers and protective layers described herein. The coating may optionally further comprise a second dielectric layer. The second dielectric layer may be any of the dielectric layers described herein. The coating may optionally further comprise a base layer. The base layer may be any of the base layers described herein.

The coated articles described herein can be used in an architectural transparency, such as, but not limited to, an insulating glass unit. As used herein, the term “architectural transparency” refers to any transparency located on a building, such as, but not limited to, windows and sky lights. However, it is to be understood that the invention is not limited to use with such architectural transparencies but could be practiced with transparencies in any desired field, such as, but not limited to, laminated or non-laminated residential and/or commercial windows, insulating glass units, and/or transparencies for land, air, space, above water and underwater vehicles. Therefore, it is to be understood that the specifically disclosed exemplary embodiments are presented simply to explain the general concepts of the invention, and that the invention is not limited to these specific exemplary embodiments. Additionally, while a typical “transparency” can have sufficient visible light transmission such that materials can be viewed through the transparency, in the practice of the invention, the “transparency” need not be transparent to visible light but may be translucent or opaque.

A non-limiting insulating glass unit 110 incorporating features of the invention is provided in FIG. 1B. The insulating glass unit 110 includes a first ply 112 with a first major surface 114 (No. 1 surface) and an opposed second major surface 116 (No. 2 surface). In the illustrated non-limiting embodiment, the first major surface 114 faces the building exterior, i.e., is an outer major surface, and the second major surface 116 faces the interior of the building. The insulating glass unit 110 also includes a second ply 118 having an outer (first) major surface 120 (No. 3 surface) and an inner (second) major surface 122 (No. 4 surface) and spaced from the first ply 112. In some embodiments, the insulating glass unit includes a third ply with a No. 5 surface and an opposed No. 6 surface. This numbering of the ply surfaces is in keeping with conventional practice in the fenestration art. The plies 112, 118 can have any desired visible light, infrared radiation, or ultraviolet radiation transmission and/or reflection. For example, the plies 112, 118 can have a visible light transmission of any desired amount, e.g., greater than 0% up to 100%.

The plies 112, 118 can each be, for example, clear float glass or can be tinted or colored glass or one ply 112, 118 can be clear glass and the other ply 112, 118 colored glass. Although not limiting to the invention, examples of glass suitable for the first ply 112 and/or second ply 118 are described in U.S. Pat. Nos. 4,746,347; 4,792,536; 5,030,593; 5,030,594; 5,240,886; 5,385,872; and 5,393,593.

The first and second plies 112, 118 can be connected together in any suitable manner, such as by being adhesively bonded to a conventional spacer frame 124. A gap or chamber 126 is formed between the two plies 112, 118. The chamber 126 can be filled with a selected atmosphere, such as air, or a non-reactive gas such as argon or krypton gas. A coating 130 is formed over at least a portion of one of the plies 112, 118, such as, but not limited to, over at least a portion of the No. 2 surface 116 or at least a portion of the No. 3 surface 120. Although, the coating 130 could also be on the No. 1 surface 114 or the No. 4 surface 122, if desired. The coating 130 may comprise, consist essentially of, or consist of any of the coatings described herein. Examples of insulating glass units are found, for example, in U.S. Pat. Nos. 4,193,236; 4,464,874; 5,088,258; and 5,106,663.

The invention is further described in the following numbered clauses:

Clause 1. A coated article comprising: a substrate; and a metal functional layer over at least a portion of the substrate; wherein the metal functional layer comprises a metal alloy selected from the group consisting of a silicon aluminum alloy and a silicon cobalt alloy.

Clause 2. The coated article of clause 1, wherein the metal functional layer has a thickness in the range of 20 nm to 40 nm, from 20 nm to 60 nm, from 30 nm to 45 nm, or from 20 nm to 30 nm.

Clause 3. The coated article of clause 1 or 2, wherein the metal functional layer comprises from 60 wt. % to 99 wt. % silicon.

Clause 4. The coated article of any one of clauses 1 to 3, wherein the metal functional layer comprises a silicon aluminum alloy or a silicon cobalt alloy.

Clause 5. The coated article of any one of clauses 1 to 4, wherein the metal functional layer comprises from 70 wt. % to 100 wt. % silicon and from 0 wt. % to 30 wt. % aluminum, from 80 wt. % to 95 wt. % silicon and from 5 wt. % to 20 wt. % aluminum, or from 85 wt. % to 95 wt. % silicon and from 5 wt. % to 15 wt. % aluminum.

Clause 6. The coated article of any one of clauses 1 to 4, wherein the metal functional layer comprises from 30 wt. % to 85 wt. % silicon and from 15 wt. % to 70 wt. % cobalt, or from 50 wt. % to 70 wt. % silicon and from 30 wt. % to 50 wt. % cobalt.

Clause 7. The coated article of any one of clauses 1 to 6, wherein the metal functional layer is essentially free, substantially free, or completely free of iron.

Clause 8. The coated article of any one of clauses 1 to 7, further comprising a protective layer over the metal functional layer.

Clause 9. The coated article of clause 8, wherein the protective layer comprises a metal oxide layer, a metal nitride layer, or mixtures thereof.

Clause 10. The coated article of clause 8 or 9, wherein the protective layer comprises titania, silica, alumina, silicon oxide, silica aluminum oxide, silicon nitride, silicon aluminum nitride, silicon aluminum oxynitride, zirconia, or mixtures thereof.

Clause 11. The coated article of any one of clauses 8 to 10, wherein the protective layer has a thickness of from 5 nm to 70 nm, from 5 nm to 30 nm, from 30 nm to 70 nm, or from 10 nm to 30 nm.

Clause 12. The coated article of any one of clauses 1 to 11, further comprising a base layer over the substrate and under the metal functional layer.

Clause 13. The coated article of clause 12, wherein the base layer has a thickness of from 30 nm to 110 nm, from 30 nm to 80 nm, or from 70 nm to 110 nm.

Clause 14. The coated article of any one of clauses 1 to 13, further comprising at least one dielectric layer.

Clause 15. The coated article of clause 14, wherein the dielectric layer comprises one or more films selected from zinc tin oxides, zinc oxide, silica, silicon aluminum oxides, silicon nitride, aluminum nitride, silicon aluminum nitrides, titanium oxides, and titanium nitrides.

Clause 16. The coated article of clause 14 or 15 wherein each dielectric layer has a thickness of from 5 nm to 140 nm, from 80 nm to 120 nm, from 100 nm to 140 nm, or from 1 nm to 10 nm.

Clause 17. The coated article of any one of clauses 1 to 16, wherein the substrate is a glass substrate.

Clause 18. A coated article comprising: a glass substrate; and a coating over at least a portion of the substrate, the coating comprising: a dielectric layer over the substrate; a metal functional layer; and a protective layer over the metal functional layer; wherein the metal functional layer comprises a metal alloy selected from the group consisting of a silicon aluminum alloy and a silicon cobalt alloy.

Clause 19. The coated article of clause 18, wherein the metal functional layer resides over the dielectric layer.

Clause 20. The coated article of clause 18 or 19, further comprising a second dielectric layer over the metal functional layer; wherein the protective layer resides over the second dielectric layer.

Clause 21. The coated article of any of clauses 18 to 20, further comprising a base layer over the dielectric layer; wherein the metal functional layer resides over the base layer.

Clause 22. The coated article of clause 18 or 20, wherein the dielectric layer resides over the protective layer.

Clause 23. The coated article of any of clauses 18 to 22, wherein the metal functional layer has a thickness in the range of 20 nm to 40 nm, from 20 nm to 60 nm, from 30 nm to 45 nm, or from 20 nm to 30 nm.

Clause 24. The coated article of any one of clauses 18 to 23, wherein the metal functional layer comprises from 60 wt. % to 99 wt. % silicon.

Clause 25. The coated article of any one of clauses 18 to 24, or 32, wherein the metal functional layer comprises a silicon aluminum alloy or a silicon cobalt alloy.

Clause 26. The coated article of any one of clauses 18 to 24, wherein the metal functional layer comprises from 70 wt. % to 100 wt. % silicon and from 0 wt. % to 30 wt. % aluminum, from 80 wt. % to 95 wt. % silicon and from 5 wt. % to 20 wt. % aluminum, or from 85 wt. % to 95 wt. % silicon and from 5 wt. % to 15 wt. % aluminum.

Clause 27. The coated article of any one of clauses 18 to 24, wherein the metal functional layer comprises from 30 wt. % to 85 wt. % silicon and from 15 wt. % to 70 wt. % cobalt, or from 50 wt. % to 70 wt. % silicon and from 30 wt. % to 50 wt. % cobalt.

Clause 28. The coated article of any one of clauses 18 to 27, wherein the metal functional layer is essentially free, substantially free, or completely free of iron.

Clause 29. The coated article of any one of clauses 18 to 28, wherein the dielectric layer comprises one or more films selected from zinc tin oxides, zinc oxide, silica, silicon aluminum oxides, silicon nitride, aluminum nitride, silicon aluminum nitrides, titanium oxides, and titanium nitrides.

Clause 30. The coated article of any of clauses 18 to 29 wherein the dielectric layer comprises silicon nitride or silicon aluminum nitride.

Clause 31. The coated article of any one of clauses 18 to 30, wherein the dielectric layer has a thickness of from 5 nm to 140 nm, from 80 nm to 120 nm, from 100 nm to 140 nm, or from 1 nm to 10 nm.

Clause 32. The coated article of any one of clauses 18 to 31, wherein the protective layer comprises a metal oxide layer, a metal nitride layer, or mixtures thereof.

Clause 33. The coated article of any of clauses 18 to 32, wherein the protective layer comprises at least one of titania, silica, alumina, silicon oxide, silica aluminum oxide, silicon nitride, silicon aluminum nitride, silicon aluminum oxynitride, zirconia, or mixtures thereof.

Clause 34. The coated article of any one of clauses 18 to 33, wherein the protective layer has a thickness of from 5 nm to 70 nm, from 5 nm to 30 nm, from 30 nm to 70 nm, or from 10 nm to 30 nm.

Clause 35. The coated article of any one of clauses 21 or 23 to 34, wherein the base layer has a thickness of from 30 nm to 110 nm, from 30 nm to 80 nm, or from 70 nm to 110 nm.

Clause 36. A method of making a coated article, comprising: providing a substrate; and forming a metal functional layer over at least a portion of the substrate; wherein the metal functional layer comprises a metal alloy selected from the group consisting of a silicon aluminum alloy and a silicon cobalt alloy; and wherein the metal functional layer is formed by a process comprising depositing, by a magnetron sputtering vapor deposition method, the metal alloy.

Clause 37. The method of clause 36, wherein the metal functional layer has a thickness in the range of 20 nm to 40 nm, from 20 nm to 60 nm, from 30 nm to 45 nm, or from 20 nm to 30 nm.

Clause 38. The method of clause 36 or 37, wherein the metal functional layer comprises from 60 wt. % to 99 wt. % silicon.

Clause 39. The method of any one of clauses 36 to 38, wherein the metal functional layer comprises a silicon aluminum alloy or a silicon cobalt alloy.

Clause 40. The method of any one of clauses 36 to 39, wherein the metal functional layer comprises from 70 wt. % to 100 wt. % silicon and from 0 wt. % to 30 wt. % aluminum, from 80 wt. % to 95 wt. % silicon and from 5 wt. % to 20 wt. % aluminum, or from 85 wt. % to 95 wt. % silicon and from 5 wt. % to 15 wt. % aluminum.

Clause 41. The method of any one of clauses 36 to 39, wherein the metal functional layer comprises from 30 wt. % to 85 wt. % silicon and from 15 wt. % to 70 wt. % cobalt, or from 50 wt. % to 70 wt. % silicon and from 30 wt. % to 50 wt. % cobalt.

Clause 42. The method of any one of clauses 36 to 41, wherein the metal functional layer is essentially free, substantially free, or completely free of iron.

Clause 43. The method of any one of clauses 36 to 42, further comprising a protective layer over the metal functional layer.

Clause 44. The method of clause 43, wherein the protective layer comprises a metal oxide layer, a metal nitride layer, or mixtures thereof.

Clause 45. The method of clause 43 or 44, wherein the protective layer comprises titania, silica, alumina, silicon oxide, silica aluminum oxide, silicon nitride, silicon aluminum nitride, silicon aluminum oxynitride, zirconia, or mixtures thereof.

Clause 46. The method of any one of clauses 43 to 45, wherein the protective layer has a thickness of from 5 nm to 70 nm, from 5 nm to 30 nm, from 30 nm to 70 nm, or from 10 nm to 30 nm.

Clause 47. The method of any one of clauses 36 to 46, further comprising a base layer over the substrate and under the metal functional layer.

Clause 48. The method of clause 47, wherein the base layer has a thickness of from 30 nm to 110 nm, from 30 nm to 80 nm, or from 70 nm to 110 nm.

Clause 49. The method of any one of clauses 36 to 48, further comprising at least one dielectric layer.

Clause 50. The method of clause 49, wherein the dielectric layer comprises one or more films selected from zinc tin oxides, zinc oxide, silica, silicon aluminum oxides, silicon nitride, aluminum nitride, silicon aluminum nitrides, titanium oxides, and titanium nitrides.

Clause 51. The method of clause 49 or 50 wherein each dielectric layer has a thickness of from 5 nm to 140 nm, from 80 nm to 120 nm, from 100 nm to 140 nm, or from 1 nm to 10 nm.

Clause 52. The method of any one of clauses 36 to 51, wherein the substrate is a glass substrate.

Clause 53. A method of making a coated article, comprising: providing a substrate; and forming a coating over at least a portion of the substrate; wherein the coating comprises a dielectric layer over the substrate; a metal functional layer; and a protective layer over the metal functional layer; wherein the metal functional layer comprises a metal alloy selected from the group consisting of a silicon aluminum alloy and a silicon cobalt alloy; and wherein the metal functional layer is formed by a process comprising depositing, by a magnetron sputtering vapor deposition method, the metal alloy.

Clause 54. The method of clause 53, wherein the metal functional layer resides over the dielectric layer.

Clause 55. The method of clause 53 or 54, further comprising a second dielectric layer over the metal functional layer; wherein the protective layer resides over the second dielectric layer.

Clause 56. The method of any of clauses 53 to 55, further comprising a base layer over the dielectric layer; wherein the metal functional layer resides over the base layer.

Clause 57. The method of clause 53 or 55, wherein the dielectric layer resides over the protective layer.

Clause 58. The method of any of clauses 53 to 57, wherein the metal functional layer has a thickness in the range of 20 nm to 40 nm, from 20 nm to 60 nm, from 30 nm to 45 nm, or from 20 nm to 30 nm.

Clause 59. The method of any one of clauses 53 to 58, wherein the metal functional layer comprises from 60 wt. % to 99 wt. % silicon.

Clause 60. The method of any one of clauses 53 to 59, or 67, wherein the metal functional layer comprises a silicon aluminum alloy or a silicon cobalt alloy.

Clause 61. The method of any one of clauses 53 to 59, wherein the metal functional layer comprises from 70 wt. % to 100 wt. % silicon and from 0 wt. % to 30 wt. % aluminum, from 80 wt. % to 95 wt. % silicon and from 5 wt. % to 20 wt. % aluminum, or from 85 wt. % to 95 wt. % silicon and from 5 wt. % to 15 wt. % aluminum.

Clause 62. The coated article of any one of clauses 53 to 59, wherein the metal functional layer comprises from 30 wt. % to 85 wt. % silicon and from 15 wt. % to 70 wt. % cobalt, or from 50 wt. % to 70 wt. % silicon and from 30 wt. % to 50 wt. % cobalt.

Clause 63. The method of any one of clauses 53 to 62, wherein the metal functional layer is essentially free, substantially free, or completely free of iron.

Clause 64. The method of any one of clauses 53 to 63, wherein the dielectric layer comprises one or more films selected from zinc tin oxides, zinc oxide, silica, silicon aluminum oxides, silicon nitride, aluminum nitride, silicon aluminum nitrides, titanium oxides, and titanium nitrides.

Clause 65. The method of any of clauses 53 to 64, wherein the dielectric layer comprises silicon nitride or silicon aluminum nitride.

Clause 66. The method of any one of clauses 53 to 65, wherein the dielectric layer has a thickness of from 5 nm to 140 nm, from 80 nm to 120 nm, from 100 nm to 140 nm, or from 1 nm to 10 nm.

Clause 67. The method of any one of clauses 53 to 66, wherein the protective layer comprises a metal oxide layer, a metal nitride layer, or mixtures thereof.

Clause 68. The method of any of clauses 53 to 67, wherein the protective layer comprises at least one of titania, silica, alumina, silicon oxide, silica aluminum oxide, silicon nitride, silicon aluminum nitride, silicon aluminum oxynitride, zirconia, or mixtures thereof.

Clause 69. The method of any one of clauses 53 to 68, wherein the protective layer has a thickness of from 5 nm to 70 nm, from 5 nm to 30 nm, from 30 nm to 70 nm, or from 10 nm to 30 nm.

Clause 70. The method of any one of clauses 56 or 58 to 69, wherein the base layer has a thickness of from 30 nm to 110 nm, from 30 nm to 80 nm, or from 70 nm to 110 nm.

The following Examples illustrate various embodiments of the invention. However, it is to be understood that the invention is not limited to these specific embodiments.

### Examples

Table 1 shows exemplary coated articles 1-3 of the invention. The reported thicknesses are physical thicknesses in nanometers (nm). The substrate was 6 mm clear glass. A base layer was deposited on the glass surface. Silicon aluminum metal alloy (SiAl, 95 wt. % silicon and 5 wt. % aluminum) was deposited on the base layer. A protective silicon aluminum oxide layer (SiAlOₓ) was deposited over the SiAl layer.

TABLE 1

| Sample | 1 | 2 | 3 |
|---|---|---|---|
| SiAlOₓ | 10 nm | 10 nm | 10 nm |
| SiAl metal | 30 nm | 40 nm | 45 nm |
| Base layer | 40 nm | 40 nm | 40 nm |
| Substrate | 6 mm glass | 6 mm glass | 6 mm glass |

Table 2 shows exemplary coated articles 4 and 5 of the invention. The reported thicknesses are physical thicknesses in nm. The substrate was 3.2 mm clear glass. Silicon aluminum metal alloy (95 wt. % silicon and 5 wt. % aluminum) was deposited on the glass substrate. A protective silicon aluminum oxide layer (SiAlOₓ) was deposited over the SiAl layer. A silicon aluminum nitride (SiAlN) layer was deposited over the protective layer.

TABLE 2

| | | |
|---|---|---|
| Sample | 4 | 5 |

| | | | | |
|---|---|---|---|---|
| SiAlN | 50 | nm | 50 | nm |
| SiAlOₓ | 120 | nm | 120 | nm |
| SiAl metal alloy | 28 | nm | 30 | nm |

| | | |
|---|---|---|
| Substrate | 3.2 mm glass | 3.2 mm glass |

Table 3 shows an exemplary coated article of the invention. The reported thickness is a physical thicknesses in nm. The substrate was 6 mm clear glass. A silicon aluminum nitride (SiAlNₓ) layer was deposited on the substrate. A base layer was deposited over the silicon aluminum nitride layer. Silicon aluminum metal alloy (90 wt. % silicon and 10 wt. % aluminum) was deposited on the base layer. A protective layer was deposited over the SiAl layer.

TABLE 3

| Sample | 6 |
|---|---|
| Protective layer | 16 |
| SiAl metal alloy | 25 |
| Base layer | 91 |
| SiAlNₓ | 97 |
| Substrate | 6 mm clear glass |

### Spectral Properties

Table 4 shows spectral properties for Samples 1-3 of Table 1. “T” refers to transmittance, “Rf” refers to film side or coating side reflection, and “Rg” refers to glass side reflection.

TABLE 4

| Sample | T L* | T a* | T b* | LTA | Rf L* | Rf a* | Rf b* | Rg L* | Rg a* | Rg b* |
|---|---|---|---|---|---|---|---|---|---|---|
| 1 | 51.87 | −0.39 | 7.40 | 20.51 | 80.08 | −0.44 | −2.46 | 72.35 | −2.35 | −2.89 |
| 2 | 54.18 | 0.24 | 3.70 | 22.47 | 81.70 | −3.12 | 3.06 | 77.17 | −6.38 | 3.41 |
| 3 | 54.43 | 0.13 | −0.73 | 22.34 | 80.49 | −4.10 | 11.99 | 76.01 | −7.64 | 14.40 |

Table 5 shows spectral properties for Samples 4 and 5 of Table 2.

TABLE 5

| Sample | T L* | T a* | T b* | LTA | Rf L* | Rf a* | Rf b* | Rg L* | Rg a* | Rg b* |
|---|---|---|---|---|---|---|---|---|---|---|
| 4 | 55.86 | 11.07 | 12.64 | 26.17 | 85.25 | −8.40 | −1.99 | 80.08 | −8.85 | −5.09 |
| 5 | 52.08 | 9.42 | 8.75 | 21.93 | 85.80 | −7.44 | −0.08 | 78.91 | −8.23 | −5.01 |

Table 6 shows spectral properties for Sample 6 of Table 3.

TABLE 6

| Sample | T L* | T a* | T b* | LTA | Rf L* | Rf a* | Rf b* | Rg L* | Rg a* | Rg b* |
|---|---|---|---|---|---|---|---|---|---|---|
| 6 | 46.62 | 3.95 | 3.03 | 17.89 | 81.49 | −3.45 | −1.90 | 81.62 | −6.87 | 4.10 |

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

What is claimed is:

1. A coated article comprising:
a substrate; and
a metal functional layer over at least a portion of the substrate;
wherein the metal functional layer comprises:
a metal alloy selected from the group consisting of a silicon aluminum alloy and a silicon cobalt alloy.

2. The coated article of claim 1, wherein the metal functional layer has a thickness in the range of 20 nm to 40 nm.

3. The coated article of claim 1, wherein the metal functional layer comprises from 60 wt. % to 99 wt. % silicon.

4. The coated article of claim 3, wherein the metal functional layer comprises a silicon aluminum alloy or a silicon cobalt alloy.

5. The coated article of claim 1, further comprising a protective layer over the metal functional layer.

6. The coated article of claim 5, wherein the protective layer comprises a metal oxide layer, a metal nitride layer, or mixtures thereof.

7. The coated article of claim 6, wherein the protective layer comprises titania, silica, alumina, silicon oxide, silica aluminum oxide, silicon nitride, silicon aluminum nitride, silicon aluminum oxynitride, zirconia, or mixtures thereof.

8. The coated article of claim 5, further comprising a base layer over the substrate and under the metal functional layer.

9. The coated article of claim 1, further comprising at least one dielectric layer.

10. The coated article of claim 9, wherein the dielectric layer comprises one or more films selected from zinc tin oxides, zinc oxide, silica, silicon aluminum oxides, silicon nitride, aluminum nitride, silicon aluminum nitrides, titanium oxides, and titanium nitrides.

11. The coated article of claim 1, wherein the substrate is a glass substrate.

12. A coated article comprising:
a glass substrate; and
a coating over at least a portion of the substrate, the coating comprising:
a dielectric layer over the substrate;
a metal functional layer; and
a protective layer over the metal functional layer;
wherein the metal functional layer comprises a metal alloy selected from the group consisting of a silicon aluminum alloy and a silicon cobalt alloy.

13. The coated article of claim 12, wherein the metal functional layer resides over the dielectric layer.

14. The coated article of claim 13, further comprising a second dielectric layer over the metal functional layer;
wherein the protective layer resides over the second dielectric layer.

15. The coated article of claim 13, further comprising a base layer over the dielectric layer;
wherein the metal functional layer resides over the base layer.

16. The coated article of claim 12, wherein the dielectric layer resides over the protective layer

17. The coated article of claim 12, wherein the dielectric layer comprises silicon nitride or silicon aluminum nitride.

18. The coated article of claim 15, wherein the protective layer comprises at least one of titania, silica, alumina, silicon oxide, silica aluminum oxide, silicon nitride, silicon aluminum nitride, silicon aluminum oxynitride, zirconia, or mixtures thereof.

19. A method of making a coated article, comprising:
providing a substrate; and
forming a metal functional layer over at least a portion of the substrate;
wherein the metal functional layer comprises a metal alloy selected from the group consisting of a silicon aluminum alloy and a silicon cobalt alloy; and
wherein the metal functional layer is formed by a process comprising depositing, by a magnetron sputtering vapor deposition method, the metal alloy.
